(19) United States
(12) Patent Application Publication
(10) Pub. No.: US 2023/0097547 A1
(43) Pub. Date: Mar. 30, 2023

(54) CONTROL DEVICE AND STORAGE MEDIUM

(71) Applicant: HONDA MOTOR CO., LTD., Tokyo (JP)

(72) Inventors: Jun Tsutsui, Tokyo (JP); Hajime Abe, Tokyo (JP); Yuji Fujita, Tokyo (JP); Yuya Akiyama, Tokyo (JP)

(21) Appl. No.: 17/946,077

(22) Filed: Sep. 16, 2022

(30) Foreign Application Priority Data
Sep. 29, 2021 (JP) 2021-159406

(51) Int. Cl. B60L 53/62; G01R 31/392

(52) U.S. Cl. CPC B60L 53/62; G01R 31/392

(57) ABSTRACT

A control device for an electric vehicle, in which a drive battery pack is mounted, the drive battery pack being capable of charging the plurality of battery cells using an external power supply, and the drive battery pack having a battery case for storing a plurality of battery cells in a stacked state, the control device including: a storage device that has stored a program; and a processor connected to the storage device, wherein the processor executes the program stored in the storage device to: acquire an indicator value regarding deterioration of the plurality of battery cells; and perform processing for prohibiting charging of the plurality of battery cells from the external power supply when the indicator value has reached a first threshold value.

### CROSS-REFERENCE TO RELATED APPLICATION

Priority is claimed on Japanese Patent Application No. 2021-159406, filed Sep. 29, 2021, the content of which is incorporated herein by reference.

### BACKGROUND

### Field of the Invention

The present invention relates to a control device and a storage medium.

### Description of Related Art

In recent years, there has been increasing interest in electric vehicles for CO₂ reduction in view of climate-related hazards. Electric vehicles use high-capacity batteries such as lithium-ion secondary batteries and solid-state batteries. Cells that make up a battery constitute, for example, a module, and the module is held by a module constituent member, and is designed so that the cells do not fall off when an external force such as vibration or impact is applied to the module.

Incidentally, this type of battery is restrained by restraints from both sides in a stacking direction to suppress expansion of the electrode plates in the stacking direction due to deterioration in some cases. This is because, if a distance between the electrodes increases due to the expansion, an ion movement distance becomes longer and the performance of the battery deteriorates. As the deterioration of the battery progresses, the electrode plates inside the cells harden and expand due to the generation of SEI and the cracking of secondary particles, and a reaction force against the restraints is generated in the stacking direction of the electrode plates. In relation to this, Patent Document 1 (PCT International Publication No. WO 2019/31170) discloses that the dimensional change due to charging or discharging and deterioration increases as the energy density of a prismatic battery cell is increased, and therefore it is necessary to restrain the prismatic battery cell with a relatively large force to suppress its expansion.

It is known that the reaction force tends to gradually become saturated as the deterioration of the battery progresses, but there are individual differences in this tendency. Therefore, if the reaction force continues to rise without becoming saturated, stress concentrates on a cell can, particularly a cell lid welded portion and a gas discharge valve, and cracks may occur. In this manner, if a conventional in-vehicle battery continues to be used without any special countermeasures, the in-vehicle battery may have problems according to expansion due to deterioration.

### SUMMARY

The present invention has been made in consideration of such circumstances, and one of the objects is to provide a control device and a storage medium that can prevent problems from occurring in an in-vehicle battery according to expansion due to deterioration.

A control device and a storage medium according to the present invention have adopted the following configuration.

(1): A control device according to one aspect of the present invention is a control device for an electric vehicle, in which a drive battery pack is mounted , the drive battery pack being capable of charging the plurality of battery cells using an external power supply and the drive battery pack having a battery case for storing a plurality of battery cells in a stacked state, and includes a storage device that has stored a program and a processor connected to the storage device, in which the processor executes the program stored in the storage device to: acquirean indicator value regarding deterioration of the plurality of battery cells; and perform processing for prohibiting charging of the plurality of battery cells from the external power supply when the indicator value has reached a first threshold value.

(2): In the aspect of (1) described above, the processor performs processing for prohibiting charging of the drive battery pack from the external power supply when the indicator value has risen and reached the first threshold value.

(3): In the aspect of (2) described above, the indicator value is an internal resistance value of the plurality of battery cells, or a reaction force given to a restraint by the plurality of battery cells.

(4): In the aspect of (2) described above, the processor causes an information output device capable of outputting information to an occupant in the electric vehicle to output first notification information when the indicator value has risen and reached a first threshold value.

(5): In the aspect of (4) described above, the processor causes the information output device to output second notification information when the indicator value has risen and reached a second threshold value that is a value smaller than the first threshold value.

(6): In the aspect of (1) described above, the processor performs processing of prohibiting charging of the drive battery pack from the external power supply when the indicator value has fallen and reached a first threshold value.

(7): In the aspect of (6) described above, the indicator value is a capacity retention rate of the plurality of battery cells.

(8): In the aspect of (6) described above, the processor causes an information output device capable of outputting information to an occupant in the electric vehicle to output first notification information when the indicator value has fallen and reached a first threshold value.

(9): In the aspect of (8) described above, the processor causes the information output device to output second notification information when the indicator value has fallen and reached a second threshold value that is a value larger than the first threshold value.

(10): In the aspect of (4) or (8) described above, the processor stores a transition of the indicator value in a storage device, and causes the information output device to output second notification information when the indicator value is expected to reach the first threshold value after a predetermined time or after a predetermined distance is traveled on the basis of the transition of the indicator value.

(11): In the aspect of (1) described above, each of the plurality of battery cells is a can-shaped prismatic cell, and is horizontally stacked while mounted in the electric vehicle.

(12): In the aspect of (1) described above, the first threshold value is a value determined on the basis of a structural limit of the battery cells.

(13): A storage medium according to another aspect of the present invention is a computer-readable non-transitory storage medium that has stored a program executed by a control device for an electric vehicle, in which a drive battery pack is mounted, the drive battery pack being capable of charging the plurality of battery cells using an external power supply and the drive battery pack having a battery case for storing a plurality of battery cells in a stacked state, the program causing the control device to: acquire an indicator value related to deterioration of the plurality of battery cells; and perform processing for prohibiting charging of the drive battery pack from the external power supply when the indicator value has reached a first threshold value.

According to the aspects of (1) to (13) described above, it is possible to prevent problems in an in-vehicle battery according to expansion due to deterioration.

### BRIEF DESCRIPTION OF THE DRAWINGS

FIG. 1 is a configuration diagram of an electric vehicle M to which a battery control device, which is an example of a control device, is applied.

FIG. 2 is a configuration diagram of a drive battery pack.

FIG. 3 is a configuration diagram of a battery control device.

FIG. 4 is a diagram for describing a principle by which a first threshold and a second threshold are determined.

FIG. 5 is a flowchart which shows an example of a flow of processing executed by the battery control device.

FIG. 6 is a diagram for describing another example of output control of second notification information.

### DESCRIPTION OF EMBODIMENTS

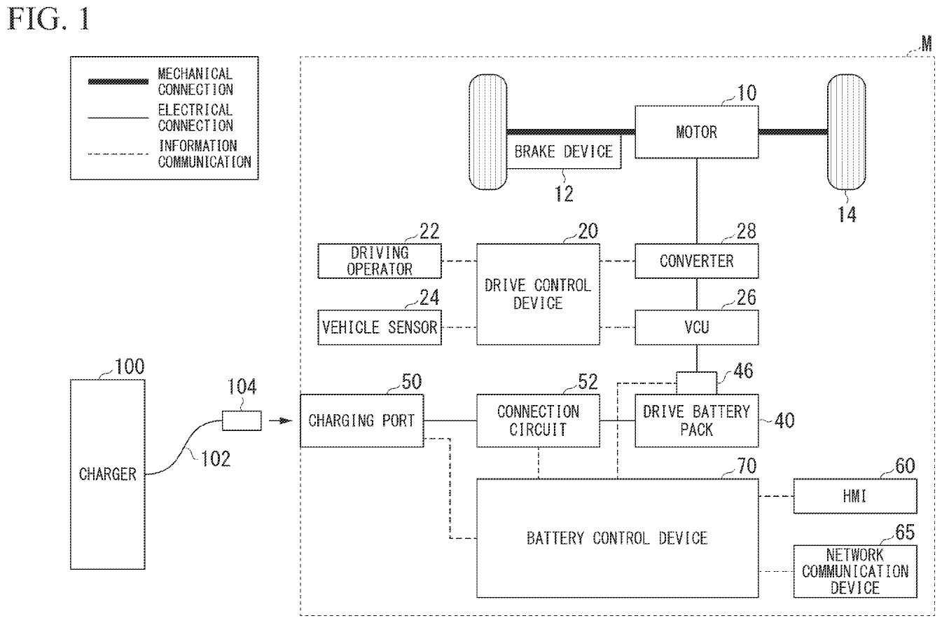

In the following description, embodiments of a control device and a storage medium of the present invention will be described with reference to the drawings. FIG. 1 is a configuration diagram of an electric vehicle M to which a battery control device 70, which is an example of a control device, is applied. The electric vehicle M is an electric vehicle that travels exclusively on electric power stored in a drive battery pack 40. The electric vehicle M includes, for example, a motor 10, a brake device 12, a drive wheel 14, a drive control device 20, a driving operator 22, a vehicle sensor 24, a VCU 26, a converter 28, the drive battery pack 40, a battery sensor 46, a charging port 50, a connection circuit 52, a communication device 54, a human machine interface (HMI) 60, the battery control device 70, and the like.

The motor 10 is, for example, a three-phase AC motor. A rotor of the motor 10 is connected to a drive wheel 14. The motor 10 uses supplied electric power to output power to the drive wheels 14. In addition, the motor 10 generates power using physical energy of a vehicle when the vehicle is decelerating.

The brake device 12 includes, for example, a brake caliper, a cylinder that transmits hydraulic pressure to the brake caliper, and an electric motor that generates the hydraulic pressure in the cylinder. The brake device 12 may include a mechanism for transmitting hydraulic pressure generated by an operation of a brake pedal to the cylinder via a master cylinder as a backup. The brake device 12 is not limited to the configuration described above, and may be an electronically controlled hydraulic brake device that transmits hydraulic pressure of the master cylinder to the cylinder.

The driving operator 22, the vehicle sensor 24, the VCU 26, the converter 28, and the like are connected to the drive control device 20. The drive control device 20 includes a hardware processor such as a central processing unit (CPU), and the processor executes a program stored in a program memory (not shown) to control the brake device 12, the VCU 26, the converter 28, and the like.

The driving operator 22 includes, for example, an accelerator pedal, a brake pedal, and the like. The driving operator 22 is provided with a sensor that detects the amount or force of operation and outputs it to the drive control device 20. The vehicle sensors 24 include, for example, a vehicle speed sensor, an acceleration sensor, a yaw rate sensor, and the like. The vehicle sensor 24 outputs a result of the detection to the drive control device 20. The VCU 26 is, for example, a DC-DC converter. The VCU 26 boosts electric power supplied from the drive battery pack 40 and outputs it to the converter 28 side. In addition, the VCU 26 supplies the electric power, which is generated by the motor 10 and converted into direct current by the converter 28, to the drive battery pack 40. The converter 28 is, for example, an AC-DC converter. The converter 28 converts the electric power supplied from the VCU 26 into alternating current and supplies it to the motor 10.

In the configuration described above, the drive control device 20 determines torque to be output by the motor 10 on the basis of an operation amount of the accelerator pedal and a speed of the electric vehicle M, and controls the VCU 26 and the converter 28 so that the determined torque is output. In addition, it determines a braking force to be output by the motor 10 and/or the brake device 12 on the basis of an operation amount of the brake pedal and the speed of the electric vehicle M, and controls the brake device 12, the VCU 26, and the converter 28 so that the determined braking force is output.

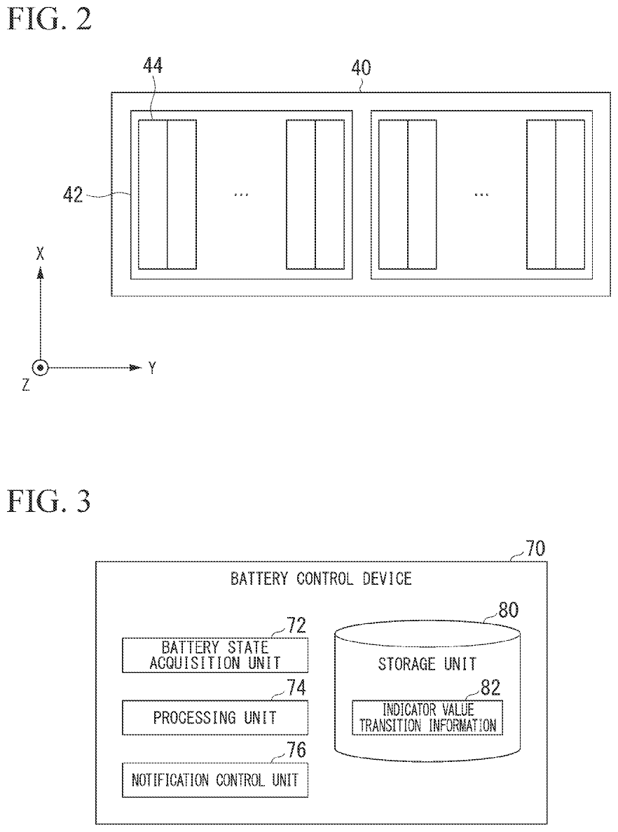

FIG. 2 is a configuration diagram of the drive battery pack 40. The drive battery pack 40 has, for example, one or more battery cases 42. Each of the battery cases 42 stores a plurality of battery cells 44 in a stacked state. In FIG. 2, the X axis is a central axis direction of the electric vehicle M, the Y axis is a width direction of the electric vehicle M, and the Z axis is a vertical direction of the electric vehicle M. The plurality of battery cells 44 are horizontally stacked with the drive battery pack 40 mounted on the electric vehicle M. Although it is shown in FIG. 2 that the plurality of battery cells 44 are stacked in a Y-axis direction, the plurality of battery cells 44 may be stacked in an X-axis direction or may be stacked diagonally with respect to the X-axis and the Y-axis. The plurality of battery cells 44 are restrained by restraints from both sides in the stacking direction. That is, a force is applied to the plurality of battery cells 44 to sandwich them from both sides in the stacking direction.

Each of the plurality of battery cells 44 is, for example, a solid-state battery with a negative electrode formed of lithium metal. Since the solid-state battery with the negative electrode formed of lithium metal expands more due to deterioration than the solid-state battery with the negative electrode formed of carbon, an effect of the present invention is large. Alternatively, each of the plurality of battery cells 44 may be a can-shaped prismatic cell containing an electrolytic solution. Each of the plurality of battery cells 44 may be a laminate cell, or may be either a modularized cell or a moduleless cell.

Returning to FIG. 1, the battery sensor 46 is attached to the drive battery pack 40. The battery sensor 46 includes, for example, a current sensor, a voltage sensor, a temperature sensor, and the like. The battery sensor 46 outputs a result of detection to the battery control device 70.

The drive battery pack 40 can transfer electric power to and from the motor 10, and can also be charged by the charger 100 outside the electric vehicle M. A charging port 50 for external charging is provided toward an outside of a vehicle body of the electric vehicle M. The charging port 50 is connected to the charger 100 via a charging cable 102. A plug 104 is provided at a tip end of the charging cable 102. The drive battery pack 40 can be charged by the plug 104 being attached to the charging port 50. In addition, the charging cable 102 may include a power cable and a signal cable, and the battery control device 70 may communicate with the charger 100 via the signal cable. In that case, the plug 104 is provided with a signal connector in addition to a power connector. A connection circuit 52 is provided between the drive battery pack 40 and the charging port 50. The connection circuit 52 electrically connects or disconnects the drive battery pack 40 and the charging port 50.

The HMI 60 is, for example, a display device, a speaker, or the like that can be attached to any place of the electric vehicle M. The HMI 60 may be a display device that displays a meter or is provided around a mechanical meter. The HMI 60 is an example of an “information output device.”

A network communication device 65 is a communication device for connecting to a wide area network such as the Internet through a cellular network or a Wi-Fi network.

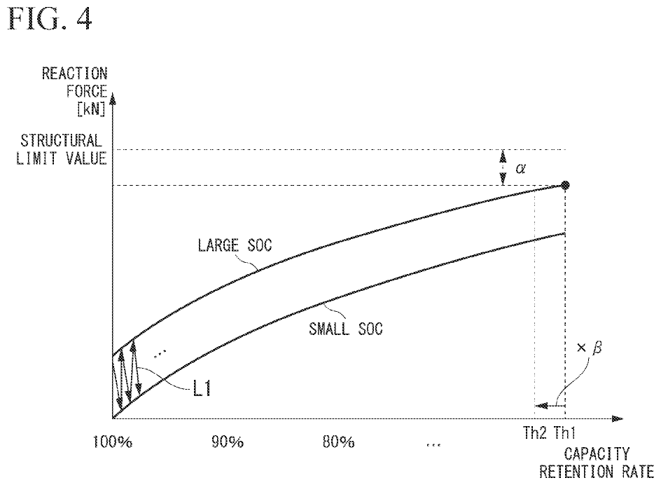

FIG. 3 is a configuration diagram of the battery control device 70. The battery control device 70 includes, for example, a battery state acquisition unit 72, a processing unit 74, a notification control unit 76, and a storage unit 80. Each of the battery state acquisition unit 72, the processing unit 74, and the notification control unit 76 is realized by, for example, a hardware processor such as a CPU executing a program (software). Some or all of these components may be realized by hardware (a circuit unit; including circuitry) such as large scale integration (LSI), an application specific integrated circuit (ASIC), a field-programmable gate array (FPGA), or a graphics processing unit (GPU), and may also be realized by software and hardware in cooperation. The program may be stored in advance in a storage device (a storage device having a non-transitory storage medium) such as a hard disk drive (HDD) or flash memory connected to the hardware processor, or may be stored in a detachable storage medium (a non-transitory storage medium) such as a DVD or CD-ROM and installed in a storage device by the storage medium being mounted in a drive device. The storage unit 80 may be the same as or may be different from the storage device in which the program is stored. The storage unit 80 is an HDD, a flash memory, a random access memory (RAM), or the like, and stores information such as the indicator value transition information 82.

The battery state acquisition unit 72 calculates a state of charge (SOC) of the drive battery pack 40, and supplies SOC information to the drive control device 20 or causes the HMI 60 to display an image regarding the SOC. The battery state acquisition unit 72 acquires (calculates) the SOC of the drive battery pack 40 on the basis of, for example, a voltage, a temperature, or a capacity retention rate to be described below of the drive battery pack 40. Since various methods are known as methods for calculating the SOC, detailed description thereof will be omitted. For example, the SOC can be obtained using a corresponding map between a voltage and SOC for each temperature.

In addition, the battery state acquisition unit 72 acquires an indicator value regarding deterioration of the plurality of battery cells 44 of the drive battery pack 40. The indicator value is a capacity retention rate of the plurality of battery cells 44, the internal resistance value, or a reaction force given to the restraint by the plurality of battery cells 44. Since a degree of deterioration is calculated by subtracting the capacity retention rate from 100%, the indicator value may be the degree of deterioration.

The battery state acquisition unit 72 calculates, for example, the capacity retention rate on the basis of a value obtained by dividing an integrated value (ΔI [Ah]) of a charging current of the drive battery pack 40 in a predetermined period by an amount of change (ΔSOC [%]) in SOC of the drive battery pack 40 in the predetermined period and an initial capacity, and acquires it. In addition, the battery state acquisition unit 72 may also obtain an internal resistance value by comparing the integrated value of the charging current of the drive battery pack 40 and the amount of change in voltage in a predetermined period. Since there is a correlation between the capacity retention rate and the internal resistance value, either one may be calculated and then the other may be calculated based on the correlation. Since various methods are also known as such a calculation method, detailed description thereof will be omitted.

The battery state acquisition unit 72 may acquire the indicator value from an external information providing device via the network communication device 65 instead of calculating or deriving the indicator value by itself. In this case, the external information providing device periodically acquires information such as the voltage, current integrated value, and temperature of the drive battery pack 40 via the network communication device 65, calculates the capacity retention rate and the internal resistance value in more detail by using a model that has been learned by machine learning, and transmits them to the electric vehicle M.

When a reaction force is acquired as an indicator value, the battery state acquisition unit 72 acquires a reaction force on the basis of a value acquired from, for example, a pressure sensor (not shown) or the like provided at a place of the drive battery pack 40 where the reaction force acts.

The processing unit 74 performs processing for prohibiting charging of the drive battery pack 40 from the charger 100, which is an external power supply, when the indicator value has reached the first threshold. “The indicator value reaches the first threshold” means “the indicator value decreases and becomes equal to or less than the first threshold value from a state of exceeding the first threshold” when the indicator value is the capacity retention rate, and means “the indicator value rises and becomes equal to or greater than the first threshold value from a state of being below the first threshold value” when the indicator value is an internal resistance value or a reaction force. That is, it means the former if the indicator value is a value that decreases as the deterioration of the plurality of battery cells 44 progresses, and it means the latter if the indicator value is a value that increases as the deterioration progresses.

The first threshold is, for example, a value determined on the basis of a structural limit of the drive battery pack 40. FIG. 4 is a diagram for describing a principle by which the first threshold value Th1 and the second threshold value Th2 (to be described below) are determined. Here, it is assumed that the indicator value is the capacity retention rate. A relationship between the capacity retention rate and the reaction force shown in FIG. 4 shows assumed state changes of the drive battery pack 40 with poor expansion rate characteristics (high expansion rate with respect to deterioration) obtained by experiments. As shown in FIG. 4, if the indicator values are the same, the reaction force generated in the drive battery pack 40 is maximized when the SOC is a first predetermined value that is large (for example, 90 to 100 [%]) and is minimized when the SOC is a second predetermined value that is small (for example, 10 to 30 [%]). Since the drive battery pack 40 is used by repeatedly charging and discharging, the reaction force changes zigzag along a transition line L1. To prevent damage to the drive battery pack 40, the first threshold value Th1 needs to be determined in consideration of the case where the SOC is the first predetermined value. The first threshold Th1 needs to be set to a capacity retention rate when the reaction force reaches a value obtained by subtracting a margin value a considering a product variation from a structural limit value (a value at which cracks or the like are expected to occur in the battery cells 44). Furthermore, the second threshold Th2 with a margin is obtained by, for example, multiplying the first threshold Th1 by a coefficient β (β is a value of about 1.2 to 1.35, or is, for example, a reciprocal thereof when the indicator value is a value that increases as the deterioration progresses). Thus, the second threshold Th2 is a value that is easier to reach than the first threshold Th1.

The processing for prohibiting charging of the plurality of battery cells 44 from the charger 100 is, for example, processing of keeping the connection circuit 52 off all the time so that charging cannot be performed even if the plug 104 is attached to the charging port 50. In addition, the processing for prohibiting charging of the plurality of battery cells 44 from the charger 100 may also be processing of notifying the charger 100 not to perform charging via a signal cable when the plug 104 is attached to the charging port 50, or the processing may be both of them.

The notification control unit 76 causes the HMI 60 to output information (an example of first notification information) indicating that charging of the drive battery pack 40 from the charger 100 is prohibited when the indicator value has reached the first threshold value Th1. Furthermore, the notification control unit 76 causes the HMI 60 to output information (an example of the second notification information) that previously notifies of prohibition of charging of the drive battery pack 40 from the charger 100 when the indicator value has reached the second threshold Th2.

Since the drive battery pack 40 cannot be charged except by regenerative power generated by the motor 10 after the indicator value has reached the first threshold value Th1, long-distance traveling is difficult. For this reason, the notification control unit 76 may cause the HMI 60 to output information that suggests a replacement of the drive battery pack 40 at a dealer or the like when the indicator value has reached the first threshold Th1.

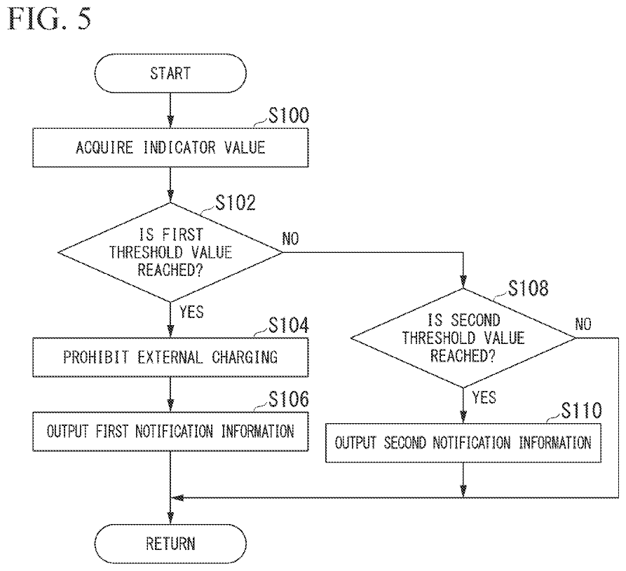

FIG. 5 is a flowchart which shows an example of a flow of processing executed by the battery control device 70. The processing of this flowchart is, for example, repeatedly executed. First, the battery state acquisition unit 72 acquires an indicator value (step S100). Next, the processing unit 74 determines whether the indicator value has reached a first threshold value Th1 (step S102). When it is determined that the indicator value has reached the first threshold Th1, the processing unit 74 performs processing for prohibiting external charging from the charger 100 (step S104). In addition, the notification control unit 76 causes the HMI 60 to output first notification information (step S106).

When it is determined that the indicator value has not reached the first threshold, the notification control unit 76 determines whether the indicator value has reached a second threshold Th2 (step S108). When it is determined that the indicator value has reached the second threshold Th2, the notification control unit 76 causes the HMI 60 to output second notification information (step S110).

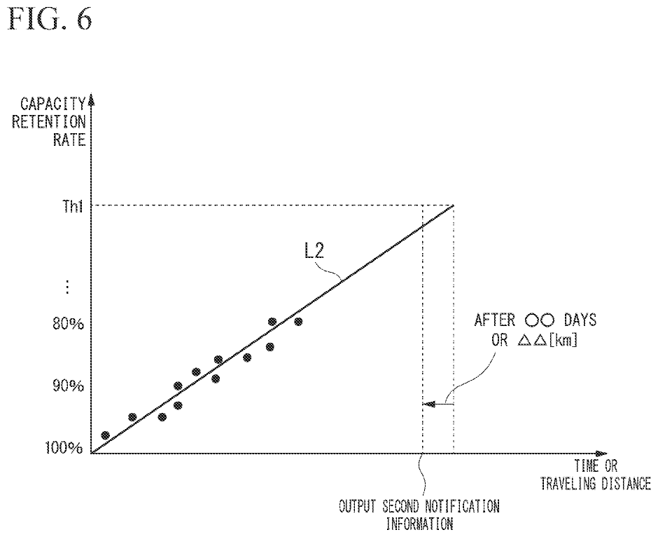

Regarding output control of the second notification information, the notification control unit 76 does not use the second threshold value Th2 defined as a fixed value, but causes the storage unit 80 to store a transition with respect to an elapsed time of the indicator value or a traveling distance of the electric vehicle M as the indicator value transition information 82, and causes the HMI 60 to output the second notification information when it is predicted that the indicator value will reach the first threshold value Th1 after a predetermined time period or a predetermined distance on the basis of the indicator value transition information 82. FIG. 6 is a diagram for describing another example of the output control of the second notification information. It is also assumed that an indicator value is a capacity retention rate in FIG. 6. Black circles in FIG. 6 represent past indicator values indicated by the indicator value transition information 82. The notification control unit 76 derives an assumed line L2 from a distribution of past indicator values by a method such as a least squares method, and causes the HMI 60 to output the second notification information when the capacity retention rate reaches the first threshold Th1 after a predetermined time has elapsed or a predetermined distance has been traveled (when the capacity maintenance rate reaches a value indicated by an intersection of a vertical dashed line corresponding to “outputting the second notification information” and the assumed line L2 in FIG. 6). As a result, it is possible to perform notification at a more appropriate timing according to the characteristics of the drive battery pack 40.

According to the embodiment described above, it is possible to prevent problems from occurring in the in-vehicle battery due to expansion associated with deterioration.

As described above, a mode for carrying out the present invention has been described using the embodiment, but the present invention is not limited to such an embodiment at all, and various modifications and substitutions can be made within a range not departing from the gist of the present invention.

What is claimed is:

1. A control device for an electric vehicle, in which a drive battery pack is mounted, the drive battery pack being capable of charging the plurality of battery cells using an external power supply, and the drive battery pack having a battery case for storing a plurality of battery cells in a stacked state, the control device comprising:
a storage device that has stored a program; and
a processor connected to the storage device,
wherein the processor executes the program stored in the storage device to:
acquire an indicator value regarding deterioration of the plurality of battery cells; and
perform processing for prohibiting charging of the plurality of battery cells from the external power supply when the indicator value has reached a first threshold value.

2. The control device according to claim 1,
wherein the processor performs processing for prohibiting charging of the drive battery pack from the external power supply when the indicator value has risen and reached the first threshold value.

3. The control device according to claim 2,
wherein the indicator value is an internal resistance value of the plurality of battery cells, or a reaction force given to a restraint by the plurality of battery cells.

4. The control device according to claim 2,
wherein the processor causes an information output device capable of outputting information to an occupant in the electric vehicle to output first notification information when the indicator value has risen and reached a first threshold value.

5. The control device according to claim 4,
wherein the processor causes the information output device to output second notification information when the indicator value has risen and reached a second threshold value that is a value smaller than the first threshold value.

6. The control device according to claim 1,
wherein the processor performs processing of prohibiting charging of the drive battery pack from the external power supply when the indicator value has fallen and reached a first threshold value.

7. The control device according to claim 6,
wherein the indicator value is a capacity retention rate of the plurality of battery cells.

8. The control device according to claim 6,
wherein the processor causes an information output device capable of outputting information to an occupant in the electric vehicle to output first notification information when the indicator value has fallen and reached a first threshold value.

9. The control device according to claim 8,
wherein the processor causes the information output device to output second notification information when the indicator value has fallen and reached a second threshold value that is a value larger than the first threshold value.

10. The control device according to claim 4,
wherein the processor stores a transition of the indicator value in a storage device, and causes the information output device to output second notification information when the indicator value is expected to reach the first threshold value after a predetermined time or after a predetermined distance is traveled on the basis of the transition of the indicator value.

11. The control device according to claim 8,
wherein the processor stores a transition of the indicator value in a storage device, and causes the information output device to output second notification information when the indicator value is expected to reach the first threshold value after a predetermined time or after a predetermined distance is traveled on the basis of the transition of the indicator value.

12. The control device according to claim 1,
wherein each of the plurality of battery cells is a can-shaped prismatic cell, and is horizontally stacked while mounted in the electric vehicle.

13. The control device according to claim 1,
wherein the first threshold value is a value determined on the basis of a structural limit of the battery cells.

14. A computer-readable non-transitory storage medium that has stored a program executed by a control device for an electric vehicle, in which a drive battery pack is mounted , the drive battery pack being capable of charging the plurality of battery cells using an external power supply and the drive battery pack having a battery case for storing a plurality of battery cells in a stacked state,
the program causing the control device to:
acquire an indicator value related to deterioration of the plurality of battery cells; and
perform processing for prohibiting charging of the drive battery pack from the external power supply when the indicator value has reached a first threshold value.
